(19) United States
(12) Patent Application Publication
(10) Pub. No.: US 2022/0238822 A1
(43) Pub. Date: Jul. 28, 2022

(54) ORGANIC LIGHT EMITTING DIODE DISPLAY PANEL AND METHOD FOR FABRICATING SAME

(71) Applicant: Wuhan China Star Optoelectronics Semiconductor Display Technology CO., Ltd., Wuhan (CN)

(72) Inventors: Rui LU, Wuhan (CN); Cunjun Xia, Wuhan (CN)

(21) Appl. No.: 16/648,638

(22) PCT Filed: Dec. 3, 2019
(86) PCT No.: PCT/CN2019/122566

§ 371 Date: Mar. 18, 2020

(30) Foreign Application Priority Data
Oct. 16, 2019 (CN) 201910981704.4

(51) Int. Cl. H01L 51/05

(52) U.S. Cl. CPC H01L 51/0508; H01L 51/56

(57) ABSTRACT

A method for fabricating an organic light emitting diode display panel includes providing a mother substrate comprising a sub-substrate defined by cutting lines and removal areas around the sub-substrate, wherein the sub-substrate comprises a active area and a non-active area surrounding the active area; forming a pixel defining layer comprising an opening on the active area; forming an organic light emitting diode in the opening; forming a dam surrounding the active area; forming a crack prevention structure surrounding the dam; forming a thin film encapsulation layer covering the pixel defining layer, the organic light emitting diode, and the dam; forming an organic protective film covering a region from a side of the dam away from the active area to the removal areas.

The present application claims priority to Chinese Patent Application No. 201910981704.4, entitled “Organic Light Emitting Diode Display Panel and Method for Fabricating Same”, filed on Oct. 16, 2019, the content of which is incorporated into the present disclosure in its entirety.

### FIELD OF INVENTION

The present disclosure relates to the technical field of organic light-emitting diode (OLED) display panels, and particularly to a method for fabricating an organic light emitting diode display panel, which reduces occurrence and expansion of cracks during a cutting process, and an organic light emitting diode display panel fabricated by the method.

### BACKGROUND

Organic light emitting diode display panels have advantages of simplicity, lightness, active light emission, fast response times, wide viewing angles, and flexibility. In a current process for fabricating organic light emitting diode display panels, a plurality of organic light emitting diode display panels are usually formed on a mother substrate, and then the organic light emitting diode display panels are cut from the mother substrate to reduce fabricating time and costs.

In a current process of cutting a mother substrate, the mother substrate and a thin film transistor (TFT) layer on cutting lines and a thin film encapsulation layer near the cutting lines are prone to cracks due to excessive stress. Furthermore, the cracks may spread to organic light emitting diodes in an active area. When moisture and oxygen in the atmosphere enter an organic light emitting diode display panel through a crack and come into contact with an organic light emitting diode, the organic light emitting diode will be corroded, thereby reducing service life of the organic light emitting diode display panel.

### SUMMARY OF DISCLOSURE

In order to solve the technical problem that a mother substrate and a thin film transistor layer on cutting lines and a thin film encapsulation layer near the cutting lines are prone to cracks due to excessive stress during cutting of the mother substrate, the present disclosure provides the following technical solutions.

The present disclosure provides a method for fabricating an organic light emitting diode display panel comprising: providing a mother substrate provided with a plurality of cutting lines, wherein the cutting lines define a sub-substrate and a plurality of removal areas around the sub-substrate, and the sub-substrate comprises a active area and a non-active area surrounding the active area; forming a pixel defining layer on the active area, wherein the pixel defining layer comprises an opening; forming an organic light emitting diode in the opening; forming a dam on the non-active area, wherein the dam is a closed ring structure surrounding the active area; forming a crack prevention structure on the non-active area, wherein the crack prevention structure is a closed ring structure surrounding the dam; forming a thin film encapsulation layer covering the pixel defining layer, the organic light emitting diode, and the dam; forming an organic protective film covering a region from a side of the dam away from the active area to the removal areas around the sub-substrate to completely cover the crack prevention structure and the cutting lines around the sub-substrate; and cutting out the sub-substrate along the cutting lines to obtain the organic light emitting diode display panel.

In an embodiment, the organic protective film further covers a region from the side of the dam away from the active area to an edge of the active area to completely cover the dam covered by the thin film encapsulation layer.

In an embodiment, with respect to the sub-substrate, a height of the organic protective film is greater than a height of the crack prevention structure.

In an embodiment, the method for fabricating the organic light emitting diode display panel further comprises forming a thin film transistor layer on the mother substrate after providing the mother substrate.

In an embodiment, the forming the thin film encapsulation layer comprises: forming a first inorganic layer covering the pixel defining layer, the organic light emitting diode, and the dam; forming an organic layer on the first inorganic layer in the active area; and forming a second inorganic layer covering the organic layer and the first inorganic layer, wherein the second inorganic layer and the first inorganic layer completely cover the organic layer.

The present disclosure further provides an organic light emitting diode display panel comprising a substrate, a pixel defining layer, an organic light emitting diode, a dam, a crack prevention structure, a thin film encapsulation layer, and an organic protective film. The substrate comprises an active area and a non-active area surrounding the active area. The pixel defining layer is disposed on the active area and comprises an opening. The organic light emitting diode is disposed in the opening. The dam is disposed on the non-active area and is a closed ring structure surrounding the active area. The crack prevention structure is disposed on the non-active area and is a closed ring structure surrounding the dam. The thin film encapsulation layer covers the pixel defining layer, the organic light emitting diode, and the dam. The organic protective film covers a region from a side of the dam away from the active area to an edge of the substrate to completely cover the crack prevention structure.

In an embodiment, the organic protective film further covers a region from the side of the dam away from the active area to an edge of the active area to completely cover the dam covered by the thin film encapsulation layer.

In an embodiment, with respect to the sub-substrate, a height of the organic protective film is greater than a height of the crack prevention structure.

In an embodiment, the organic light emitting diode display panel further comprises a thin film transistor layer disposed on the substrate and electrically connected to the organic light emitting diode.

In an embodiment, the thin film encapsulation layer comprises a first inorganic layer, an organic layer, and a second inorganic layer. The first inorganic layer covers the pixel defining layer, the organic light emitting diode, and the dam. The organic layer is disposed on the first inorganic layer in the active area. The second inorganic layer covers the organic layer and the first inorganic layer. The second inorganic layer and the first inorganic layer completely cover the organic layer.

The method for fabricating the organic light emitting diode display panel provided by the disclosure reduces the stress on the sub-substrate, the thin film encapsulation layer, and the crack prevention structure, and/or the thin film transistor layer near the cutting lines during the cutting process by covering the organic protective film made of an organic material with soft characteristics from the side of the dam away from the active area or from the edge of the active area to the removal areas outside the cutting lines. This reduces occurrence of cracks in the sub-substrate, the thin film encapsulation layer, the crack prevention structure, and/or the thin film transistor layer, and prevents the cracks, if any, from spreading to the organic light emitting diode in the active area. Furthermore, a risk of moisture and oxygen in the atmosphere entering through the cracks and corroding the organic light emitting diode is reduced, thereby ensuring service life of the organic light emitting diode display panel is ensured. Moreover, because the non-active area of the organic light emitting diode display panel made using the method provided by the present disclosure has the organic protective film, it has better ability to release stress and is less susceptible to damage by external forces, compared with a non-active area of a traditional panel.

### BRIEF DESCRIPTION OF DRAWINGS

In order to more clearly illustrate the technical solutions in the embodiments of the present disclosure, a brief description of accompanying drawings used in the description of the embodiments of the present disclosure will be given below. Obviously, the accompanying drawings in the following description are merely some embodiments of the present disclosure. For those skilled in the art, other drawings may be obtained from these accompanying drawings without creative labor.

FIG. 1 is a schematic diagram of a mother substrate used in a method for fabricating an organic light emitting diode display panel according to an embodiment of the present disclosure.

FIGS. 2-12 are schematic flowcharts of a method for fabricating an organic light emitting diode display panel according to an embodiment of the present disclosure. FIG. 2 also is a schematic cross-sectional view of the mother substrate of FIG. 1 along line AA'. FIG. 12 also is a schematic diagram of an organic light emitting diode display panel according to an embodiment of the present disclosure.

FIG. 13 is a schematic diagram showing that the first dam, the second dam, and the crack prevention structure of FIG. 7 are disposed in the non-active area.

### DETAILED DESCRIPTION

The following description of various embodiments of the present disclosure with reference to the accompanying drawings is used to illustrate specific embodiments that can be practiced. Directional terms mentioned in the present disclosure, such as “above”, “below”, “top”, “bottom”, “left”, “right”, “inside”, “outside”, “side”, are merely used to indicate the direction of the accompanying drawings. Therefore, the directional terms are used for illustrating and understanding the present disclosure rather than limiting the present disclosure. In the figures, elements with similar structures are indicated by the same reference numerals.

The present disclosure provides a method for fabricating an organic light emitting diode display panel comprising the following steps.

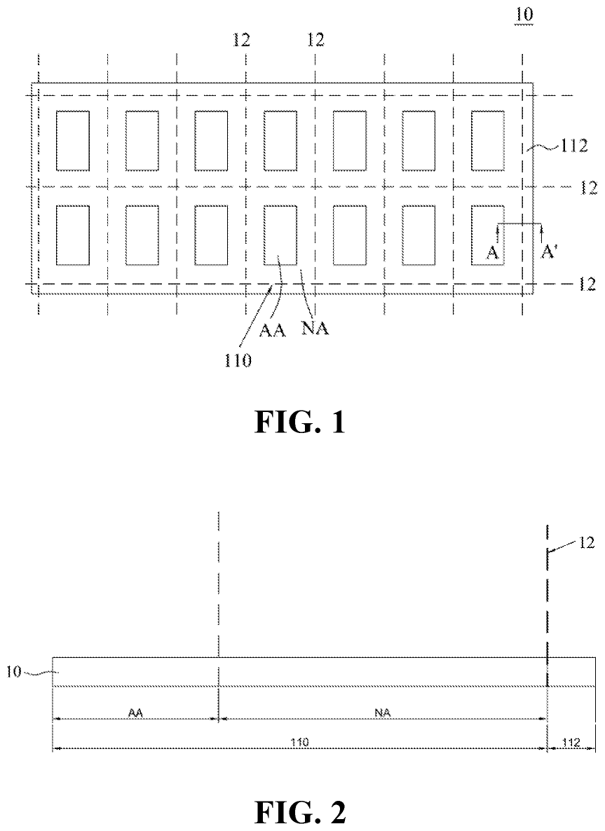

Step 1: please refer to FIG. 1 and FIG. 2, providing a mother substrate 10. The mother substrate 10 may be a glass substrate. Alternatively, the mother substrate 10 may be a flexible substrate made of a flexible insulating polymer material such as polyimide (PI), polycarbonate (PC), polyether sulfone (PES), polyethylene terephthalate (PET), polyethylene naphthalate (PEN), and film fiber-reinforced polymer (FRP). The mother substrate 10 may be transparent, translucent, or opaque. The mother substrate 10 is provided with a plurality of cutting lines 12. The cutting lines 12 define a plurality of sub-substrate 110 and a plurality of removal areas 112. Each of the sub-substrates 110 comprises an active area AA and a non-active area NA surrounding the active area AA.

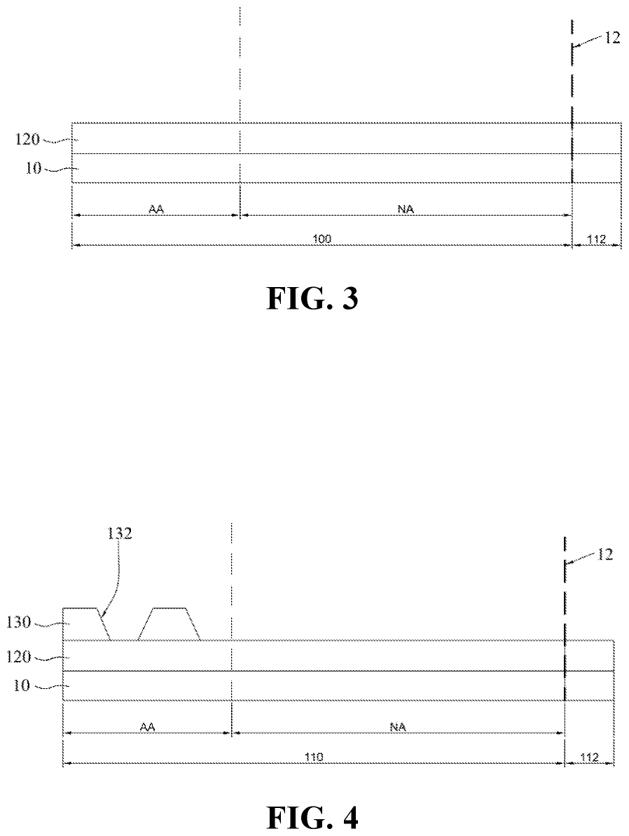

Step 2: please refer to FIG. 3, forming a thin film transistor layer 120 on the mother substrate 10. The thin film transistor layer 120 comprises a plurality of thin film transistors. Each of the thin film transistors comprises a gate electrode layer, an insulating layer, an active layer, and a source/drain electrode layer. The thin film transistors may comprise organic thin film transistors (OTFTs), hydrogenated amorphous thin film transistors (a-TFT: H), and/or low temperature poly thin film transistors (LTPS).

Step 3: please refer to FIG. 4, forming a pixel defining layer 130 on the thin film transistor layer 120 in each of the active areas AA. The pixel defining layer 130 comprises a plurality of openings 132. The pixel defining layer 130 may be made of an organic insulating material such as polyimide, acrylic, polymethyl methacrylate (PMMA) photoresist, and silicone photoresist. Alternatively, the pixel defining layer 130 may be made of an inorganic insulating material such as a silicon dioxide solution and an alcohol-containing silicon dioxide solution.

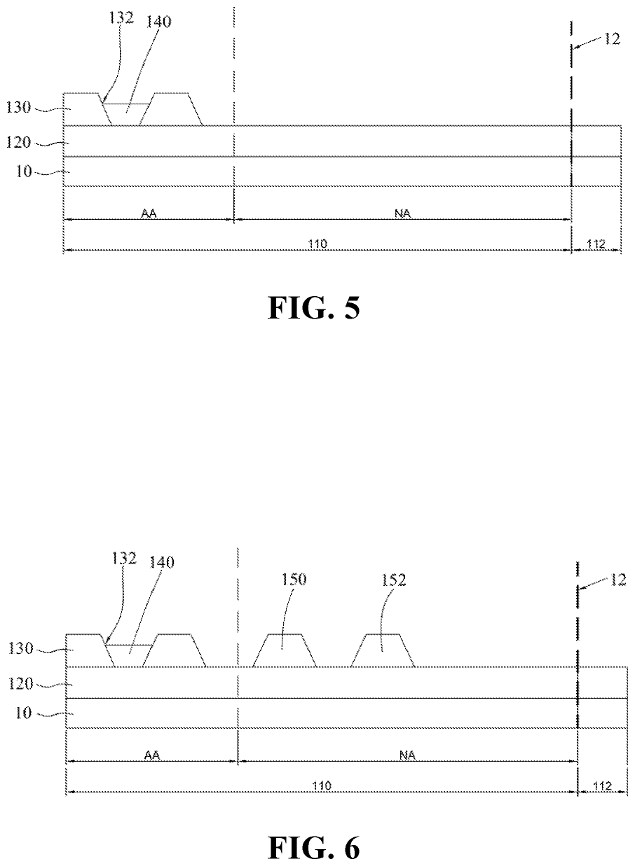

Step 4: please refer to FIG. 5, forming an organic light emitting diode 140 on the thin film transistor layer 120 in each of the openings 132. Each of the organic light emitting diodes 140 is electrically connected to one or more thin film transistors that are configured to drive it. Each of the organic light emitting diodes 140 may comprise an anode layer, a hole injection layer, a hole transport layer, a light emitting layer, an electron transport layer, an electron injection layer, and a cathode layer in this order.

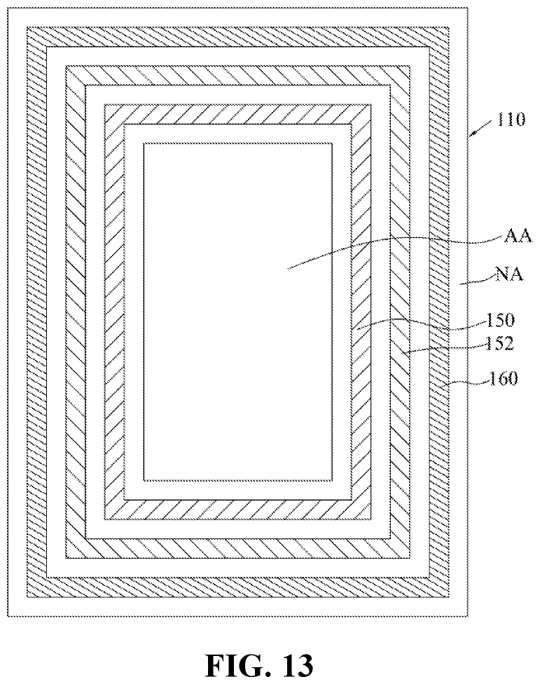

Step 5: please refer to FIG. 6 and FIG. 13, forming a first dam 150 and a second dam 152 on the thin film transistor layer 120 in each of the non-active areas NA. The first dam 150 is a closed ring structure surrounding the active area AA. The second dam 152 is a closed ring structure surrounding the first dam 150. The second dam 152 is parallel to the first dam 150. When the pixel defining layer 130 or one or more layers of each organic light emitting diode 140 is/are prepared, the first dam 150 and the second dam 152 may be made by designing their corresponding regions on one or more masks, thereby reducing production time and costs. Therefore, each of the first dam 150 and the second dam 152 has a single-layer or multi-layer structure composed of the same material(s) as the pixel defining layer 130 or one or more layers of each organic light emitting diode 140.

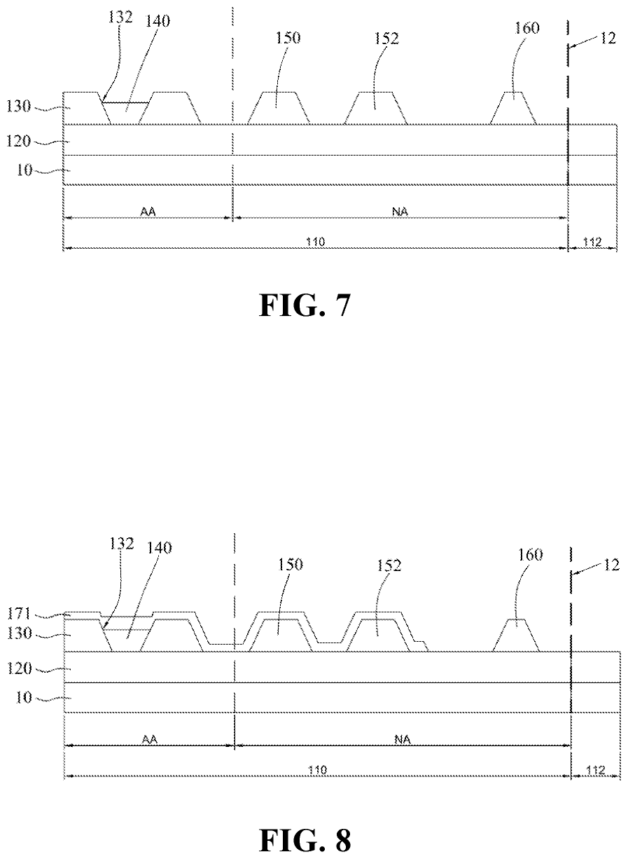

Step 6: please refer to FIG. 7 and FIG. 13, forming a crack prevention structure 160 on the thin film transistor layer 120 in each of the non-active areas NA. The crack prevention structure 160 is a closed ring structure surrounding the second dam 152. The crack prevention structure 160 is parallel to the second dam 152. The crack prevention structure 160 may be made of a flexible organic material.

Step 7: please refer to FIG. 8, forming a first inorganic layer 171 covering the pixel defining layer 130, the organic light emitting diodes 140, the first dam 150, and the second dam 152 of each sub-substrate 110 to prevent the organic light emitting diodes 140 from contact with moisture and oxygen in the atmosphere and from being corroded by moisture and oxygen in the atmosphere. The first inorganic layer 171 may be made of aluminum oxide, silicon oxide, magnesium oxide, or a combination thereof.

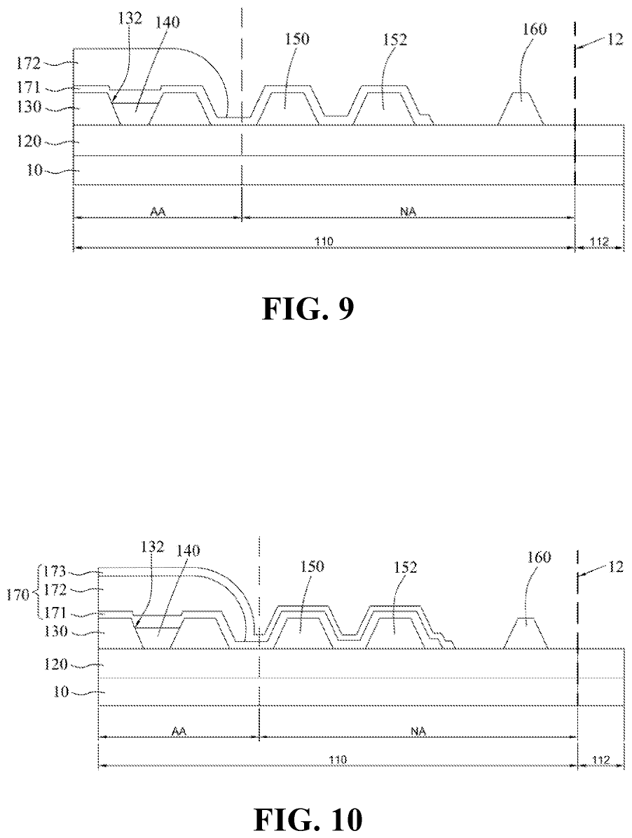

Step 8: please refer to FIG. 9, forming an organic layer 172 on the first inorganic layer 171 in each active area AA. The first dam 150 and the second dam 152 formed in step 4 can prevent the organic layer 172 from flowing out of a coverage area of the first inorganic layer 171 in the active area AA when the organic layer 172 is formed. Because the organic layer 172 is made of an organic material, it is soft and can be used to release the stress suffered by the active area AA. The organic layer 172 may be made of alucone, or may be an organic/inorganic hybrid film of aluminum, titanium, zinc, and/or iron.

Step 9: please refer to FIG. 10, forming a second inorganic layer 173 covering the organic layer 172 and the first inorganic layer 171 in each active area AA. In each active area AA, the second inorganic layer 173 and the first inorganic layer 171 completely cover the organic layer 172. Because the organic layer 172 cannot block moisture and oxygen, the second inorganic layer 173 is used to improve a blocking of moisture and oxygen. The second inorganic layer 173 may also be made of aluminum oxide, silicon oxide, magnesium oxide, or a combination thereof.

Please refer to FIG. 10, the first inorganic layer 171, the organic layer 172, and the second inorganic layer 173 in each active area AA constitute a thin film encapsulation layer 170. The thin film encapsulation layer 170 is configured to protect the organic light emitting diodes 140 in each active area AA from being damaged by moisture and oxygen in the atmosphere, and improve an ability of the active area AA to release stress. The first inorganic layer 171, the organic layer 172, and the second inorganic layer 173 may be formed by physical vapor deposition (PVD), atomic layer deposition (ALD), or chemical vapor deposition (CVD).

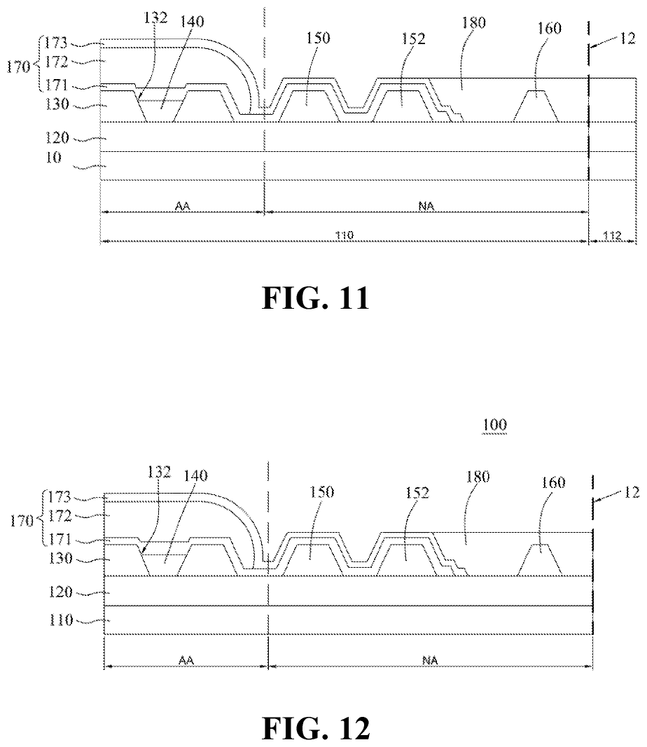

Step 10: please refer to FIG. 1 and FIG. 11, forming an organic protective film 180 covering a region from a side of the second dam 152 in each non-active area NA away from the adjacent active area AA to the adjacent removal areas 112, so as to completely cover the crack prevention structure 160 in each non-active area NA and the cutting lines 12 around each sub-substrate 110. With respect to the sub-substrate, a height of the organic protective film 180 may be equal to or greater than a height of the crack prevention structure 160, but is equal to or less than a height of the first dam 150 covered with the first inorganic layer 171 and the second inorganic layer 173.

Specifically, this step comprises blanket-depositing an organic material such as alucone and hexamethyldisiloxane (HMDSO) by ink jet printing (IJP), atomic layer deposition (ALD), chemical vapor deposition (CVD) and other processes. Further, the blanket-deposited organic material is patterned by photoengraving and etching to obtain the organic protective film 180 covering the crack prevention structure 160 in each non-active area NA and the cutting lines 12 adjacent to each non-active area NA.

In an embodiment, the organic protective film 180 covers a region from an edge of each active area AA to the adjacent removal areas 112 or an edge of another active area AA, so as to completely cover the first dam 150 and the second dam 152 covered with the thin film encapsulation layer 170 in each non-active area NA, the crack prevention structure 160, and cutting lines 12 around each sub-substrate 110. With respect to the sub-substrate 110, the height of the organic protective film 180 is greater than the height of the crack prevention structure 160 and the heights of the first dam 150 and the second dam 152 covered with the first inorganic layer 171 and the second inorganic layer 173, but is less than or equal to a height of the pixel defining layer 130 covered with the thin film encapsulation layer 170 in the active area AA.

Step 11: please refer to FIG. 1, FIG. 11, and FIG. 12, cutting out the sub-substrates 110 along the cutting lines 12 to obtain the organic light emitting diode display panels 100. Each organic light emitting diode display panel 100 is an active-matrix organic light-emitting diode (AMOLED) display panel. The crack prevention structures 160 formed in step 6 can prevent cracks of the sub-substrates 110 due to excessive stress during a cutting process from spreading. The organic protective films 180 formed in step 8 are soft, so they can release stress. This can improve a situation that the sub-substrates 110, the thin film transistor layer 120, the crack prevention structures 160, and the thin film encapsulation layers 170 near the cutting lines 12 are prone to cracks due to excessive stress during the cutting process. Further, the cracks can be prevented from spreading to the organic light emitting diodes 140 in each active area AA. Therefore, a risk of moisture and oxygen in the atmosphere entering through the cracks and corroding the organic light emitting diodes 140 is reduced, thereby ensuring service lives of the organic light emitting diode display panels 100 are ensured.

In an embodiment, the method for fabricating an organic light emitting diode display panel 100 may not comprise step 2 of forming a thin film transistor layer 120 on the mother substrate 10. Accordingly, each organic light emitting diode display panel 100 obtained in the last step is a passive-matrix organic light-emitting diode (PMOLED) display panel.

Please refer to FIG. 12, the present disclosure further provides an organic light emitting diode display panel 100 made by the foregoing method, which comprises a substrate 110, a thin film transistor layer 120, a pixel defining layer 130, an organic light emitting diode 140, a first dam 150, a second dam 152, a crack prevention structure 160, a thin film encapsulation layer 170, and an organic protective film 180. The substrate 110 may be a glass substrate. Alternatively, the substrate 10 may be a flexible substrate made of a flexible insulating polymer material such as polyimide (PI), polycarbonate (PC), polyether sulfone (PES), polyethylene terephthalate (PET), polyethylene naphthalate (PEN), and film fiber-reinforced polymer (FRP). The substrate 110 may be transparent, translucent, or opaque. The substrate 110 comprises an active area AA and a non-active area NA surrounding the active area AA.

The thin film transistor layer 120 is disposed on the substrate 110 and electronically connected to the organic light emitting diode 140. The thin film transistor layer 120 comprises a plurality of thin film transistors configured to drive the organic light emitting diode 140. Each of the thin film transistors comprises a gate electrode layer, an insulating layer, an active layer, and a source/drain electrode layer. The thin film transistors may comprise organic thin film transistors, hydrogenated amorphous thin film transistors, and/or low temperature poly thin film transistors.

The pixel defining layer 130 is disposed on the thin film transistor layer 120 in the active area AA. The pixel defining layer 130 may be made of an organic insulating material such as polyimide, acrylic, polymethyl methacrylate photoresist, and silicone photoresist. Alternatively, the pixel defining layer 130 may be made of an inorganic insulating material such as a silicon dioxide solution and an alcohol-containing silicon dioxide solution. The pixel defining layer 130 comprises an opening 132. The organic light emitting diode 140 is disposed on the thin film transistor layer 120 in the opening 132. The organic light emitting diode 140 may comprise an anode layer, a hole injection layer, a hole transport layer, a light emitting layer, an electron transport layer, an electron injection layer, and a cathode layer in this order.

The first dam 150 and the second dam 152 are disposed on the thin film transistor layer 120 in the non-active areas NA. The first dam 150 is a closed ring structure surrounding the active area AA. The second dam 152 is a closed ring structure surrounding the first dam 150. The second dam 152 is parallel to the first dam 150. The first dam 150 and the second dam 152 may have a single-layer or multi-layer structure made of same material(s) as the pixel defining layer 130 or one or more layers of the organic light emitting diode 140, thereby reducing production time and costs. The crack prevention structure 160 is disposed on the thin film transistor layer 120 in the non-active areas NA and is a closed ring structure surrounding the second dam 152. The crack prevention structure 160 is parallel to the second dam 152. The crack prevention structure 160 may be made of a flexible organic material.

The thin film encapsulation layer 170 covers the pixel defining layer 130, the organic light emitting diode 140, the first dam 150, and the second dam 152. The thin film encapsulation layer 170 comprises a first inorganic layer 171, an organic layer 172, and a second inorganic layer 173. The first inorganic layer 171 covers the pixel defining layer 130, the organic light emitting diodes 140, the first dam 150, and the second dam 152. The organic layer 172 is disposed on the first inorganic layer 171 in the active area AA. The second inorganic layer 173 covers the organic layer 172 and the first inorganic layer 171. The second inorganic layer 173 and the first inorganic layer 171 completely cover the organic layer 172. The first inorganic layer 171 and the second inorganic layer 173 are configured to prevent the organic light emitting diode 140 from contact with moisture and oxygen in the atmosphere and from being corroded by moisture and oxygen in the atmosphere. The first inorganic layer 171 and the second inorganic layer 173 may be made of aluminum oxide, silicon oxide, magnesium oxide, or a combination thereof. Because the organic layer 172 is made of an organic material, it is soft and can be used to release the stress suffered by the active area AA. The organic layer 172 may be made of alucone, or may be an organic/inorganic hybrid film of aluminum, titanium, zinc, and/or iron. The first inorganic layer 171, the organic layer 172, and the second inorganic layer 173 may be formed by physical vapor deposition, atomic layer deposition, or chemical vapor deposition.

The organic protective film 180 covers a region from a side of the second dam 152 away from the active area AA to an edge of the substrate 110, so as to completely cover the crack prevention structure 160. With respect to the sub-substrate, a height of the organic protective film 180 may be equal to or greater than a height of the crack prevention structure 160, but is equal to or less than a height of the first dam 150 covered with the first inorganic layer 171 and the second inorganic layer 173.

In an embodiment, the organic protective film 180 covers a region from an edge of the active area AA to the edge of the substrate 110, so as to completely cover the first dam 150 and the second dam 152 covered with the thin film encapsulation layer 170 in non-active area NA and the crack prevention structure 160. With respect to the substrate 110, the height of the organic protective film 180 is greater than the height of the crack prevention structure 160 and the heights of the first dam 150 and the second dam 152 covered with the first inorganic layer 171 and the second inorganic layer 173, but is less than or equal to a height of the pixel defining layer 130 covered with the thin film encapsulation layer 170 in the active area AA.

In an embodiment, the organic light emitting diode display panel 100 may not comprise the thin film transistor layer 120. Therefore, the organic light emitting diode display panel 100 is a passive-matrix organic light-emitting diode display panel.

In the above, the method for fabricating the organic light emitting diode display panel provided by the disclosure achieves the following effects by using the organic protective films 180. The organic protective films 180 are made of an soft organic material and cover the region from the side of the second dam 152 in each non-active area NA away from the adjacent active area AA, or the edge of each active area AA, to the adjacent removal areas 112 (1) The organic protective films 180 can release the stresses suffered by the sub-substrates 110 and the crack prevention structures 160 adjacent to the cutting lines 12 when the sub-substrates 110 are cut from the mother substrate 10. This prevents the sub-substrates 110 from cracking, prevents cracks from spreading to the thin film encapsulation layers 170, and prevents the crack prevention structures 160 from being damaged and losing their effectiveness. (2) The organic protective films 180 can also release the stress suffered by the thin film encapsulation layers 170 adjacent to the cutting lines 12 during the cutting process. When the first inorganic layer 171 and the second inorganic layer 173 of each thin-film encapsulation layer 170 are made by a method such as chemical vapor deposition, materials of the inorganic layers easily enters between masks and the sub-substrate 110 to form a thin film. That is a shadow effect. When the thin film covers the crack prevention structure 160, especially when the organic light emitting diode display panel has a narrow frame design, the organic protective film 180 can release the stresses suffered by the first inorganic layer 171 and the second inorganic layer 173 that covers on the crack prevention structure 160 during the cutting of the sub-substrate 110 from the mother substrate 10. This can prevent the first inorganic layer 171 and the second inorganic layer 173 from cracking, and prevent the cracking from causing the thin film encapsulation layer 170 to fail. (3) When the organic light emitting diode display panels 100 are an active matrix organic light emitting diode display panel, the thin film transistor layer 120 is disposed on the mother substrate 10. The portions of the thin film transistor layer 120 located near the cutting lines 12 and near the crack prevention structures 160 are mainly composed of a metal layer and an inorganic layer, and therefore cannot release stress. The organic protective film 180 can release the stresses suffered by the portions of the thin film transistor layer 120 located near the cutting lines 12 and near the crack prevention structures 160 when the sub-substrates 110 are cut from the mother substrate 10, thereby preventing the thin film transistor layer 120 from cracking and preventing cracks from expanding to the thin film encapsulation layers 170. Furthermore, because the non-active area NA of the organic light-emitting diode display panel 100 made by using the method provided by the present disclosure is provided with the organic protective film 180, it has an ability to release stress. Therefore, compared with a non-active area of a current panel, it is not easily damaged by external forces.

The present application has been described in the above preferred embodiments, but the preferred embodiments are not intended to limit the scope of the present application, and those skilled in the art may make various modifications without departing from the scope of the present application. The scope of the present application is determined by claims.

1. A method for fabricating an organic light emitting diode display panel, comprising:
providing a mother substrate provided with a plurality of cutting lines, wherein the cutting lines define a sub-substrate and a plurality of removal areas around the sub-substrate, and the sub-substrate comprises an active area and a non-active area surrounding the active area;
forming a pixel defining layer on the active area, wherein the pixel defining layer comprises an opening;
forming an organic light emitting diode in the opening;
forming a dam on the non-active area, wherein the dam is a closed ring structure surrounding the active area;
forming a crack prevention structure on the non-active area, wherein the crack prevention structure is a closed ring structure surrounding the dam;
forming a thin film encapsulation layer covering the pixel defining layer, the organic light emitting diode, and the dam;
forming an organic protective film covering a region from a side of the dam away from the active area to the removal areas around the sub-substrate to completely cover the crack prevention structure and the cutting lines around the sub-substrate; and
cutting out the sub-substrate along the cutting lines to obtain the organic light emitting diode display panel.

2. The method for fabricating the organic light emitting diode display panel according to claim 1, wherein the organic protective film further covers a region from the side of the dam away from the active area to an edge of the active area to completely cover the dam covered by the thin film encapsulation layer.

3. The method for fabricating the organic light emitting diode display panel according to claim 1, wherein a height of the organic protective film with respect to the sub-substrate is greater than a height of the crack prevention structure with respect to the sub-substrate.

4. The method for fabricating the organic light emitting diode display panel according to claim 1, further comprising: after providing the mother substrate, forming a thin film transistor layer on the mother substrate.

5. The method for fabricating the organic light emitting diode display panel according to claim 1, wherein the forming the thin film encapsulation layer comprises:
forming a first inorganic layer covering the pixel defining layer, the organic light emitting diode, and the dam;
forming an organic layer on the first inorganic layer in the active area; and
forming a second inorganic layer covering the organic layer and the first inorganic layer, wherein the second inorganic layer and the first inorganic layer completely cover the organic layer.

6. An organic light emitting diode display panel, comprising:
a substrate comprising an active area and a non-active area surrounding the active area;
a pixel defining layer disposed on the active area and comprising an opening;
an organic light emitting diode disposed in the opening;
a dam disposed on the non-active area, which is a closed ring structure surrounding the active area;
a crack prevention structure disposed on the non-active area, which is a closed ring structure surrounding the dam;
a thin film encapsulation layer covering the pixel defining layer, the organic light emitting diode, and the dam; and
an organic protective film covering a region from a side of the dam away from the active area to an edge of the substrate to completely cover the crack prevention structure.

7. The organic light emitting diode display panel according to claim 6, wherein the organic protective film further covers a region from the side of the dam away from the active area to an edge of the active area to completely cover the dam covered by the thin film encapsulation layer.

8. The organic light emitting diode display panel according to claim 6, wherein a height of the organic protective film with respect to the sub-substrate is greater than a height of the crack prevention structure with respect to the sub-substrate.

9. The organic light emitting diode display panel according to claim 6, further comprising: a thin film transistor layer disposed on the substrate and electrically connected to the organic light emitting diode.

10. The organic light emitting diode display panel according to claim 6, wherein the thin film encapsulation layer comprises:
a first inorganic layer covering the pixel defining layer, the organic light emitting diode, and the dam;
an organic layer disposed on the first inorganic layer in the active area; and
a second inorganic layer covering the organic layer and the first inorganic layer, wherein the second inorganic layer and the first inorganic layer completely cover the organic layer.
